(19) United States
(12) Patent Application Publication
(10) Pub. No.: US 2025/0130109 A1
(43) Pub. Date: Apr. 24, 2025

(54) DETECTION ELEMENT AND ELECTRONIC DEVICE

(71) Applicant: SONY SEMICONDUCTOR SOLUTIONS CORPORATION, KANAGAWA (JP)

(72) Inventor: RIN TAKAHASHI, KANAGAWA (JP)

(21) Appl. No.: 18/834,152

(22) PCT Filed: Jan. 19, 2023
(86) PCT No.: PCT/JP2023/001467

§ 371 Date: Jul. 29, 2024

(30) Foreign Application Priority Data
Feb. 7, 2022 (JP) 2022-017494

(51) Int. Cl. G01J 5/08; G01J 5/12

(52) U.S. Cl. CPC G01J 5/08; G01J 5/12

(57) ABSTRACT

To provide an advantageous feature for reducing the effects of warping attributable to thermal stress in a detection element capable of receiving electromagnetic waves (infrared and/or terahertz waves). The detection element includes an absorption layer configured to receive an electromagnetic wave included in at least a part of a wavelength range from 100 μm to 3000 μm to generate heat, a thermoelectric element configured to generate current corresponding to the heat generated by the absorption layer, and a support having an accommodation space in which the absorption layer is positioned. The accommodation space has a first accommodation opening located on a side on which the electromagnetic wave is incident and a second accommodation opening located on an opposite side to the first accommodation opening. The absorption layer exposed through the second accommodation opening has an area smaller than the first accommodation opening does.

### TECHNICAL FIELD

The present disclosure relates to a detection element and an electronic device.

### BACKGROUND ART

Infrared and terahertz waves, which have longer wavelengths than visible light, are less susceptible to scattering, have high material permeability, and are low energy waves, making these waves highly safe. As a result, the use of infrared and terahertz waves in imaging technology have become widespread. Typically, imaging techniques using infrared and terahertz waves are used in security applications such as hazardous materials monitoring, and nondestructive testing applications such as internal screening.

PTL 1 discloses an infrared sensor that uses an infrared absorbing film and thermopile. PTL 2 discloses a multilayer structure including an element structure that detects electromagnetic waves in the terahertz band.

### CITATION LIST

### Patent Literature

[PTL 1]

JP 2011-203225A

[PTL 2]

JP 2013-160556A

### SUMMARY

### Technical Problem

Detection elements that can receive infrared or terahertz waves may warp due to thermal stress caused by the temperature rise when the detection elements are placed in a high-temperature environment or generate heat during manufacturing or use.

In the infrared sensor in PTL 1, the stress concentration is relaxed by providing a stress-relaxing structure part having multiple holes. However, in the infrared sensor in PTL 1, the structural strength of the infrared sensor is reduced by the holes formed in the stress-relaxing structure part of the thin film.

In the multilayer structure in PTL 2, a stress-relaxing layer formed on the substrate reduces the warpage of the substrate. However, as in the multilayer structure in PTL 2, the presence of such a thin-film structure under the absorber that receives detection waves, such as terahertz waves, increases the heat capacity, which is disadvantageous in terms of the time constant.

The present disclosure provides an advantageous feature for reducing the effects of warping attributable to thermal stress in a detection element capable of receiving electromagnetic waves (infrared and/or terahertz waves).

### Solution to Problem

One aspect of the present disclosure relates to a detection element including an absorption layer configured to receive an electromagnetic wave included in at least a part of a wavelength range from 100 μm to 3000 μm to generate heat, a thermoelectric element configured to generate current corresponding to the heat generated by the absorption layer, and a support having an accommodation space in which the absorption layer is positioned, the accommodation space has a first accommodation opening located on a side on which the electromagnetic wave is incident and a second accommodation opening located on an opposite side to the first accommodation opening, and the absorption layer exposed through the second accommodation opening has an area smaller than the first accommodation opening does.

The absorption layer may have a first layer surface and a second layer surface that is located on an opposite side to the first layer surface and partly exposed through the second accommodation opening, and the support may be partly in contact with the second layer surface.

The second accommodation opening may have an area which is at least 10% of a projected area of the first layer surface with respect to a stacking direction in which the absorption layer and the support are stacked on each other.

The second accommodation opening may have an area which is at most 75% of a projected area of the first layer surface with respect to a stacking direction in which the absorption layer and the support are stacked on each other.

The absorption layer may have a linear expansion coefficient greater than the support does.

The difference between the linear expansion coefficient of the absorption layer and the linear expansion coefficient of the support may be at least 6 ppm/K.

The second accommodation opening may have a polygonal planar shape.

The second accommodation opening may have a circular or oval planar shape.

The second accommodation opening may have a plurality of partial openings that are separated from each other.

The support may have a stepped surface that partitions the accommodation space and is in contact with the absorption layer.

The absorption layer may have a plurality of steps.

The first layer surface may have a plurality of step-shaped portions.

A part of the absorption layer exposed through the second accommodation opening may curve toward the first accommodation opening as the temperature of the absorption layer rises.

The support may have an opening partition that extends in a direction perpendicular to the stacking direction in which the absorption layer and the support are stacked on each other and partitions the second accommodation opening, at least a part of the absorption layer may be located on the opening partition, and the opening partition may curve toward the first accommodation opening as the temperature rises.

The detection element may further include a structural member opposed to a part of the absorption layer exposed through the second accommodation opening.

The support may have an insulating property.

Another aspect of the present disclosure relates to an electronic device comprising a detection device, the detection device includes an absorption layer configured to receive an electromagnetic wave included in at least a part of a wavelength range from 100 μm to 3000 μm to generate heat, a thermoelectric element that generates current corresponding to the heat generated by the absorption layer; and a support having an accommodation space in which the absorption layer is positioned, the accommodation space has a first accommodation opening located on a side on which the electromagnetic wave is incident and a second accommodation opening located on an opposite side to the first accommodation opening, and the absorption layer exposed through the second accommodation opening having an area smaller than the first accommodation opening does.

### BRIEF DESCRIPTION OF DRAWINGS

FIG. 1 is a schematic view of an example of an imaging system that can be used for body checking of a subject.

FIG. 2 is a side cross-sectional view of an example of a detection element.

FIG. 3 is a plan view of the detection element shown in FIG. 2.

FIG. 4 is a side cross-sectional view for illustrating an example of the operation of the detection element shown in FIG. 2.

FIG. 5 is a side cross-sectional view of a detection element according to Example 1 of a first embodiment.

FIG. 6 is a plan view of the absorption layer and the support in FIG. 5 (particularly a view of the absorption layer and the support as viewed from below in FIG. 5).

FIG. 7 is a side cross-sectional view for illustrating an example of the operation of the detection element shown in FIG. 5.

FIG. 8 is a view of the detection element (particularly the detection element according to Example 1) used as a simulation model, showing various sizes thereof.

FIG. 9 is a side cross-sectional view of an example of the detection element according to Example 1, showing various sizes thereof.

FIG. 10 is a graph showing simulation results about the displacement amount of the absorption layer regarding Comparative Example 1 and Example 1.

FIG. 11 is a side cross-sectional view of a detection element according to Example 2 of the first embodiment.

FIG. 12 is a plan view of the absorption layer and the support shown in FIG. 11 (particularly a view of the absorption layer and the support as viewed from below in FIG. 11).

FIG. 13 is a graph showing simulation results about the displacement amount of the absorption layer regarding Comparative Example 1 and Example 2.

FIG. 14 is a side cross-sectional view of a detection element according to Example 3 of the first embodiment.

FIG. 15 is a plan view of the absorption layer and the support shown in FIG. 14 (particularly a view of the absorption layer and the support as viewed from below in FIG. 14).

FIG. 16 is a graph showing simulation results about the displacement amount of the absorption layer regarding Comparative Example 1 and Example 3.

FIG. 17 is a side cross-sectional view of a detection element according to Comparative Example 2.

FIG. 18 is a plan view of the support shown in FIG. 17 (particularly a view of the support from below in FIG. 17).

FIG. 19 is a graph showing simulation results about the displacement amount of the absorption layer regarding Comparative Examples 1 and 2 and Examples 1 to 3.

FIG. 20 is a graph showing simulation results about the heat capacity of the detection element regarding Comparative Examples 1 and 2 and Examples 1 to 3.

FIG. 21 is a side cross-sectional view of an example of a detection element according to a second embodiment.

### DESCRIPTION OF EMBODIMENTS

Hereinafter, typical embodiments of the present disclosure will be described with reference to the drawings. The sizes of the individual elements and the scales between the elements do not necessarily coincide between the drawings, but a person skilled in the art would be able to appropriately understand the elements shown in the drawings.

In the following description, terms indicating directions such as “upper,” “lower,” “left,” and “right” are used merely for convenience to describe the state shown in the corresponding drawings, unless otherwise specified, and do not limit the orientation during actual use. Therefore, the orientation of the device in actual use may or may not coincide with the orientation of the device shown in each of the drawings.

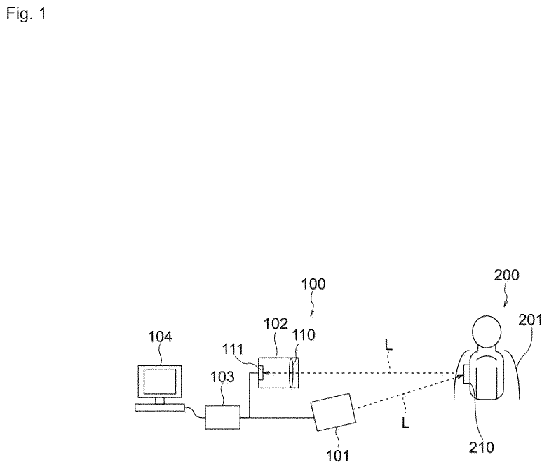

FIG. 1 is a schematic view of an example of an imaging system 100 that can be used for body checking of a subject 200.

The imaging system 100 shown in FIG. 1 includes a wave transmission unit 101, a wave receiving unit 102, a control unit 103, and a terminal device 104.

The wave transmission unit 101 emits a detection wave L toward the subject 200 under the control of the control unit 103.

Electromagnetic waves called infrared and terahertz waves having a frequency band about in the range of 0.1 THz to 3 THz are preferable for the detection wave L, and electromagnetic waves in a relatively broad wavelength range may also be used. As an example, electromagnetic waves included in at least a part of the wavelength range from 100 μm to 3000 μm (e.g., 100 μm to 1000 μm) can be used as the detection wave L.

The detection wave L with such a wavelength characteristic which transmits through clothing 201 worn by the subject 200 is reflected by a portable article 210 possessed by the subject 200. Therefore, by detecting the detection wave L reflected by the subject 200 with the wave receiving unit 102, the portable article 210, which is hidden by the clothing 201, can be found.

The wave receiving unit 102 includes an optical system 110 and an imaging unit 111. A part of the detection wave L reflected by the subject 200 is guided by the optical system 110 to the imaging unit 111 and is captured by the imaging unit 111.

The imaging unit 111 includes a plurality of detection elements, which will be described below, and each of the detection elements detects the detection wave L. Each of the detection elements sends a detection signal corresponding to the received detection wave L to the control unit 103.

The control unit 103 analyzes the detection signals sent from the imaging unit 111 (i.e., the plurality of detection elements) to acquire information necessary for determining whether the subject 200 is in possession of the portable article 210. Specifically, the control unit 103 can reproduce a captured image of the portable article 210 on the basis of the detection signals and display the image on the display of a terminal device 104 as visual information or output an audio sound from the speaker of the terminal device 104 as audio information.

The imaging system 100 described above can be suitably used for human body inspections, typically performed at airports, but the system can be used at any location and for any application.

Now, the detection elements provided in the imaging unit 111 of the imaging system (electronic device) 100 will be described.

### First Embodiment

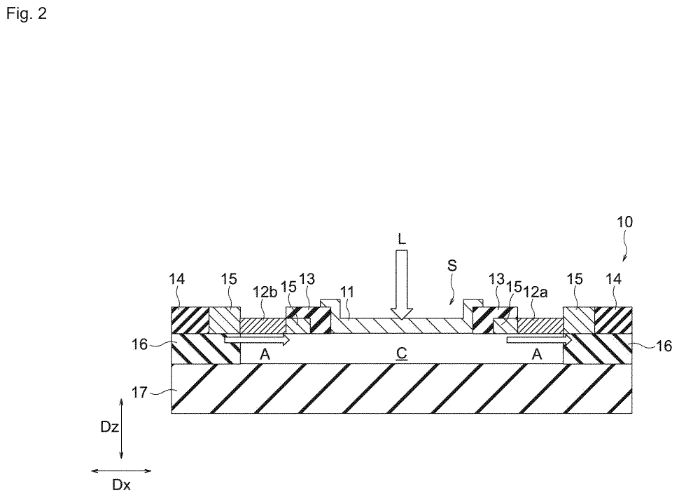

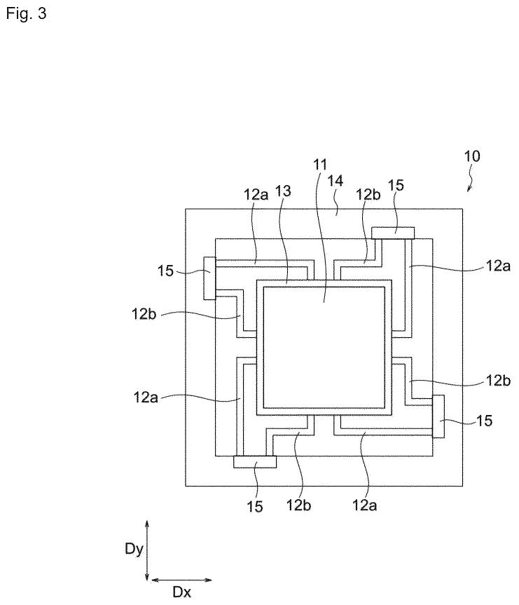

FIG. 2 is a side cross-sectional view of an example of a detection element 10. FIG. 3 is a plan view of the detection element 10 shown in FIG. 2.

The imaging unit 111 (see FIG. 1) includes a plurality of detection elements 10 as shown in FIGS. 2 and 3. The arrangement of the plurality of detection elements 10 is not limited. The imaging unit 111 typically includes a two-dimensional array including a plurality of detection elements 10 in two-dimensional arrangement but may also include a one-dimensional array including a plurality of detection elements 10 in one-dimensional arrangement.

The detection element 10 shown in FIGS. 2 and 3 includes an absorption layer 11 that generates heat upon receiving the detection wave L, thermoelectric elements 12a and 12b that generate current corresponding to the heat emitted by the absorption layer 11, and a support 13 which supports the absorption layer 11.

In the example shown in FIG. 2, the outer periphery of the absorption layer 11 is in contact with the support 13 without any gap therebetween, and is located further apart from the substrate 17 than the support 13 with respect to a stacking direction Dz. Meanwhile, the center part of the absorption layer 11 has a recessed shape toward the substrate 17 with respect to the periphery part, and the top surface of the center part is located closer to the substrate 17 (the lower side in FIG. 2) than the top surface of the periphery part of the absorption layer 11 and the top surface of the support 13. The bottom surface of the support 13 and the bottom surface of the absorption layer 11 are located flush without a step in the same plane extending in a direction perpendicular to the stacking direction Dz (see extension directions Dx and Dy).

The support 13 is made of an electrically insulating insulator and is positioned between the absorption layer 11 and the thermoelectric elements 12a and 12b. The support 13 in this example has an accommodation space S in which at least a part of the absorption layer 11 is positioned. The accommodation space S shown in FIGS. 2 and 3 is defined by a cuboid-shaped through hole extending in the stacking direction Dz, and is partitioned by an inner wall surface of the support 13 extending in a direction coincident with the stacking direction Dz.

The thermoelectric elements 12a and 12b convert heat into electricity and generate current (see the arrows labeled “A” in FIG. 2) according to the temperature difference within each element (temperature gradient). The thermoelectric elements 12a and 12b in this example include a plurality of first thermoelectric elements 12a which generate current from the high temperature side to the low temperature side and a plurality of second thermoelectric elements 12b which generate current from the low temperature side to the high temperature side.

The opposite ends of each of the thermoelectric elements 12a and 12b are connected to a leads 15. The current generated by the thermoelectric elements 12a and 12b is sent as detection signals to an external device (see the control unit 103 in FIG. 1) through the leads 15.

One end of each of the thermoelectric elements 12a and 12b is connected to the absorption layer 11 through one lead 15 and the support 13 that covers the lead 15. The other lead 15, which is connected to the other end of each of the thermoelectric elements 12a and 12b, is supported by a first insulating layer 14 and a second insulating layer 16. The first insulating layer 14 and the lead 15 are positioned on the substrate 17 through the second insulating layer 16. The second insulating layer 16 has a frame shape with through holes and supports the first insulating layer 14 and the lead 15.

The through hole in the second insulating layer 16 defines a cavity portion C. The cavity portion C is adjacent to the absorption layer 11, the support 13, and the thermoelectric elements 12a and 12b on one side in the stacking direction Dz (the upper side in FIG. 2) and adjacent to the substrate 17 on the other side in the stacking direction Dz (the lower side in FIG. 2). Therefore, the absorption layer 11, the support 13, and the thermoelectric elements 12a and 12b are opposed to the substrate (structural member) 17 in the stacking direction Dz through the cavity portion C which defines a space.

In this way, the cavity portion C is a space enclosed by the second insulating layer 16, the absorption layer 11, the support 13, the thermoelectric elements 12a and 12b, and the substrate 17. The cavity portion C may be sealed by a surrounding member (which may include elements not shown) or may be provided as a vacuum space having a pressure lower than the surrounding environmental pressure (e.g., atmospheric pressure), or any gas may be enclosed in the cavity portion C.

In the detection element 10 having the configuration described above, the absorption layer 11 generates heat corresponding to the detection wave L incident on the detection element 10, and the thermal energy due to the heat generation is transferred to the thermoelectric elements 12a and 12b through the support 13 and converted into electricity by the thermoelectric elements 12a and 12b. In this way, the detection element 10 generates an electrical detection signal corresponding to the received detection wave L and sends the detection signal from the thermoelectric elements 12a and 12b to an external device through the leads 15.

The elements described above that constitute the detection element 10 can be formed using any materials.

The absorption layer 11 may typically include a fibrous material and a 2D material with a two-dimensional extent. More specifically, the absorption layer 11 may include graphene nanoribbons, carbon fibers, CNTs (carbon nanotubes), and/or metal nanowires as the fibrous material and graphene as the 2D material.

The thermoelectric elements 12a and 12b may include a thermal conversion material such as polysilicon (Poly-Si) and silicon germanium (SiGe), a bolometer material such as amorphous silicon (a-Si) and vanadium oxide (VOx), or any of other materials with pyroelectric effects. When the thermoelectric elements 12a and 12b are made of polysilicon, the first thermoelectric element 12a can be made of p-type polysilicon (p-Poly-Si) and the second thermoelectric element 12b can be made of n-type polysilicon (n-Poly-Si).

The support 13 and the first insulating layer 14 can typically be made of silicon nitride (SiN) or silicon dioxide (SiO₂). The second insulating layer 16 may typically be made of silicon dioxide. The substrate 17 may typically be made of silicon (Si) or glass.

The detection element 10 having the layered structure described above can be manufactured by any known method, utilizing the most suitable method for the material, such as chemical vapor deposition (CVD) and coating.

The overall size of the detection element 10 and the size of the individual elements in the detection element 10 are not basically limited.

However, the size per pixel (pixel pitch) defined by the individual detection elements 10 is preferably determined according to the wavelength of the detection wave L so that each detection element 10 can properly receive the detection wave L. In other words, the pixel pitch of the detection element 10 (the size of one detection element 10 in the extension directions Dx and Dy) is larger than or equal to the wavelength of the detection wave L.

As an example, when the detection wave L has a frequency of 1 THz, the pixel pitch of the detection element 10 is preferably at least about 300 μm. For example, the detection element 10 having a pixel pitch of 300 μm can properly receive electromagnetic waves having a frequency of 1 THz or higher. In this way, the pixel pitch of the detection element 10 is preferably determined in consideration of not only a desired imaging resolution but also the wavelength (frequency) of the detection wave L that is actually used.

As described above, the absorption layer 11 of the detection element 10 generates heat and its temperature rises upon the incidence of the detection wave L. Also, in implementing packaging (vacuum packaging) of the detection element 10, the entire detection element 10 is heated to a very high temperature (e.g., about 400° C.).

The absorption layer 11 may bend due to the thermal stresses attributable to such a temperature rise while the product is manufactured or used. In other words, if the thermal expansion of the absorption layer 11 caused by the temperature increase is prevented by the support 13, which consequently, causes the absorption layer 11 (especially the center part, which is not directly supported by the support 13) to bend in the stacking direction Dz.

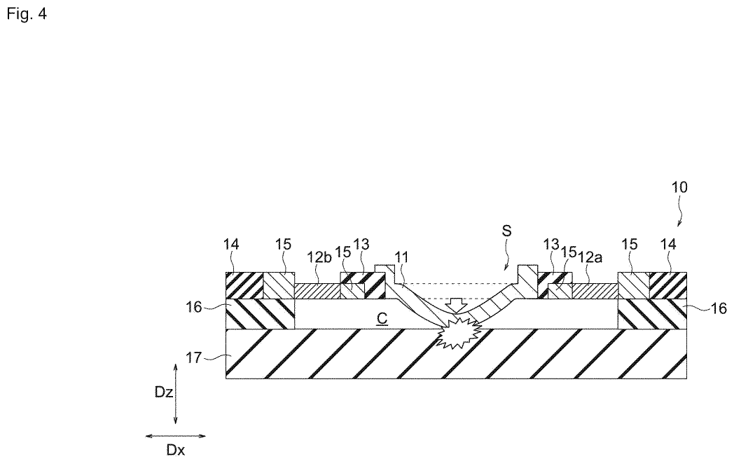

If the degree of bending of the absorption layer 11 increases and the absorption layer 11 warps significantly toward the substrate 17, as shown in FIG. 4, the absorption layer 11 may accidentally contact the substrate 17, and in some cases, the absorption layer 11 and/or the substrate 17 may be damaged. In particular, the size (depth) of the cavity portion C in the stacking direction Dz is usually very small. Therefore, if the absorption layer 11 warps toward the substrate 17, accidental contact between the absorption layer 11 and the substrate 17 can easily occur.

To avoid such accidental contact between the absorption layer 11 and the substrate 17, it may be effective to increase the depth of the cavity portion C in the stacking direction Dz. However, when the depth of cavity portion C is increased, the size of the entire detection element 10 in the stacking direction Dz also increases. It is not always easy to form the cavity portion C with a large depth in the second insulating layer 16 either. In the manufacture of the detection element 10, for example, the second insulating layer 16 (SiO₂) is first deposited on the substrate 17, and then the absorption layer 11, the thermoelectric elements 12a and 12b, the support 13, the first insulating layer 14, and the leads 15 are formed. The cavity portion C can then be created by supplying a processing medium (e.g., gaseous dry hydrofluoric acid) into numerous small holes (not shown) formed in the absorption layer 11 and dissolving and removing the central part of the second insulating layer 16 by the processing medium. In this case, the processing medium dissolves and removes the second insulating layer 16 in the stacking direction Dz as well as in the extension direction Dx, but the second insulating layer 16 must remain at the outer periphery of the detection element 10. Therefore, there is a limit to the dissolution and removal of the second insulating layer 16 in the extension direction Dx, and this limit in the extension direction Dx inevitably limits the dissolution and removal of the second insulating layer 16 in the stacking direction Dz. In this way, since the amount of how much the second insulating layer 16 can be dissolved and removed in the stacking direction Dz is limited by the amount of how much the second insulating layer 16 can be dissolved and removed in the extension direction Dx, the cavity portion C having a large depth in the stacking direction Dz cannot be formed in the second insulating layer 16 in some cases.

Accidental contact between the absorption layer 11 and the substrate 17 can be avoided by reducing the amount of warpage of the absorption layer 11 when the temperature rises. For example, the amount of warpage of the absorption layer 11 and the substrate 17 caused when the temperature rises can be effectively reduced by forming the absorption layer 11 using a material with low temperature deformation or a material with high rigidity, or by forming a peripheral member such as the support 13 that supports the absorption layer 11 using a material with low rigidity. However, in these cases, the materials that can be used to form the absorption layer 11 and the support 13 are limited, and flexibility in selection of materials may not always be secured.

The inventor has diligently researched and newly found that accidental contact between the absorption layer 11 and the substrate 17 can be effectively avoided by intentionally controlling the direction in which the absorption layer 11 warps when the temperature rises. In other words, the inventor has newly found that accidental contact between the absorption layer 11 and the substrate 17 can be effectively avoided by making the detection element 10 have a configuration such that the absorption layer 11 (especially the part of the absorption layer 11 opposed to the substrate 17) warps in the direction away from the substrate 17 (upward in FIG. 4) when the temperature rises.

Hereinafter, an exemplary specific configuration of the detection element 10 that allows the effectively avoidance of accidental contact between the absorption layer 11 and the substrate 17 will be described.

### Example 1

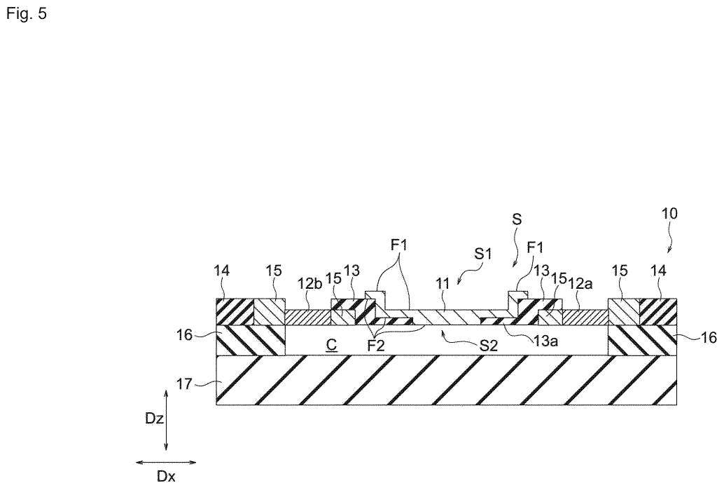

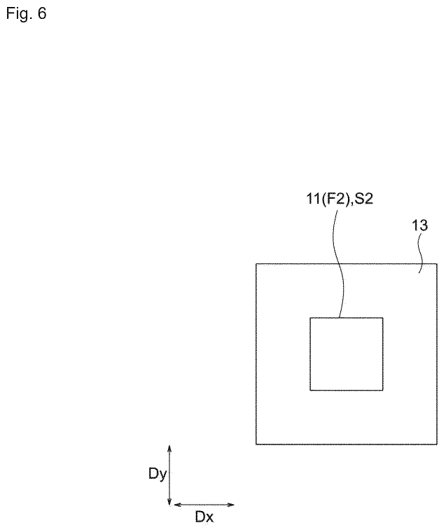

FIG. 5 is a side cross-sectional view of a detection element 10 according to Example 1 of a first embodiment. FIG. 6 is a plan view of the absorption layer 11 and the support 13 in FIG. 5 (particularly a view of the absorption layer 11 and the support 13 as viewed from below in FIG. 5).

In the present embodiment, elements that are the same as or correspond to those in the above-described detection element 10 shown in FIGS. 2 and 3 will be denoted by the same reference signs, and detailed descriptions thereof will not be provided.

The accommodation space S of the support 13 has a first accommodation opening S1 located on the side where the detection wave L is incident and a second accommodation opening S2 located on the opposite side to the first accommodation opening S1 (i.e., on the side of the substrate 17) with respect to the stacking direction Dz. In other words, the opposite ends of the accommodation space in the stacking direction Dz of the accommodation space S are formed by the first and second accommodation openings S1 and S2, respectively.

The support 13 has an opening partition 13a that partitions the second accommodation opening S2. The opening partition 13a extends inwardly from the outer periphery of the support 13 in a direction perpendicular to the stacking direction Dz of the absorption layer 11 and the support 13 (see the extension direction Dx and Dy).

At least a part of the absorption layer 11 (in the example shown in FIG. 5, the middle part located between the outer periphery and the center of the absorption layer 11) is located on the opening partition 13a and on the opposite side to the substrate 17 through the opening partition 13a. In this way, the support 13 has a stepped surface that partitions the accommodation space S and is in contact with a part of the back surface (second layer surface F2) of the absorption layer 11.

The second accommodation opening S2 in this example has a polygonal (particularly quadrangular (square)) planar shape, as shown in FIG. 6. The size and area of the second accommodation opening S2 are not limited but determined so that the projected area of the entire absorption layer 11 and the projected area of the part of the absorption layer 11 exposed through the second accommodation opening S2 are in a desired ratio, as will be described below.

The absorption layer 11 has a first layer surface F1 located on the side on which the detection wave L is incident and a second layer surface F2 located on the opposite side to the first layer surface F1 with respect to the stacking direction Dz (i.e., the side of the substrate 17). The first layer surface F1 constitutes the surface (front surface of the absorption layer 11) on which the detection wave L is incident.

The second layer surface F2, which constitutes the back surface (rear surface) of the absorption layer 11, is partly exposed through the second accommodation opening S2. In the example shown in FIGS. 5 and 6, the center part of the second layer surface F2 is exposed through the second accommodation opening S2 toward the cavity portion C while the support 13 is in contact with a part of the second layer surface F2 (particularly the outer periphery). The part of the absorption layer 11 exposed through the second accommodation opening S2 is opposed to the substrate (structural member) 17 in the stacking direction Dz through the cavity portion C.

In the example shown in FIGS. 5 and 6, the part of the absorption layer 11 exposed through the second accommodation opening S2 fills the entire cuboid-shaped space region of the accommodation space S partitioned by the opening partition 13a. Therefore, the bottom surface of the support 13 (including the bottom surface of the opening partition 13a) and the bottom surface of the part of the absorption layer 11 exposed through the second accommodation opening S2 are located without steps in the same plane extending in the direction perpendicular to the stacking direction Dz (see the extension directions Dx and Dy).

In this way, in the detection element 10 in this example, the area of the second accommodation opening S2 exposed through the second accommodation opening S2 (i.e., the projected area in the stacking direction Dz) is smaller than the area of the first accommodation opening S1 (i.e., the projected area in the stacking direction Dz).

For example, the area of the second accommodation opening S2 may be at least 10% of the projected area of the first layer surface F1 of the absorption layer 11 with respect to the stacking direction Dz (i.e., the direction in which the absorption layer 11 and the support 13 are stacked). The area of the second accommodation opening S2 may be at most 75% of the projected area of the first layer surface F1 of the absorption layer 11 with respect to the stacking direction Dz.

The “projected area” of the first layer surface F1 here is the area of the part of the first layer surface F1 that is visible when the first layer surface F1 as viewed in the stacking direction Dz, and is the size occupied by the first layer surface F1 with respect to the direction perpendicular to the stacking direction Dz.

The linear expansion coefficient (CTE: Coefficient of Thermal Expansion) of the absorption layer 11 is greater than that of the support 13 (the linear expansion coefficient of the absorption layer 11>the linear expansion coefficient of the support 13). For example, the difference (absolute value) between the linear expansion coefficient of the absorption layer 11 and the linear expansion coefficient of the support 13 may be at least 6 ppm/K.

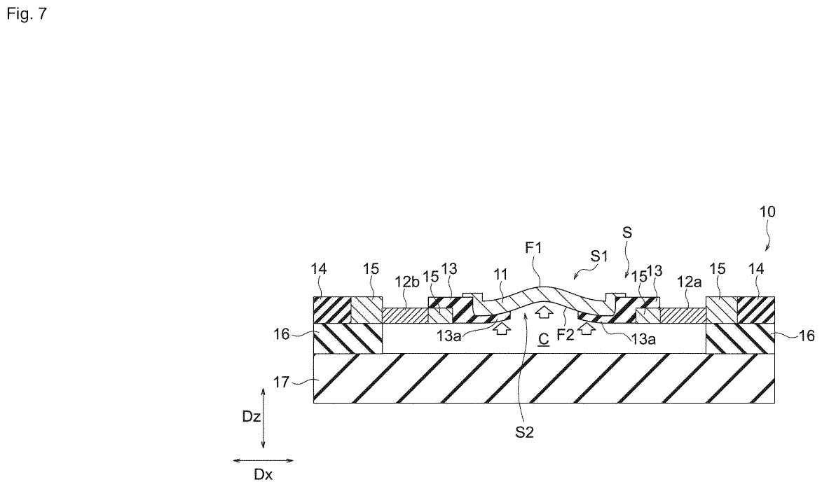

As shown in FIG. 7, the detection element 10 in this example having the exemplary configuration described above is advantageous for bending the absorption layer 11 toward the first accommodation opening S1, which is the opposite side to the substrate 17 when the temperature rises.

Specifically, as the temperature of the absorption layer 11 rises, the part of the absorption layer 11 exposed through the second accommodation opening S2 (i.e., the center part) is highly likely to curve toward the first accommodation opening S1. In particular, the opening partition 13a of the support 13 is also highly likely to curve toward the first accommodation opening S1 as the temperature rises. Therefore, the part of the absorption layer 11 exposed through the second accommodation opening S2 is even more likely to curve toward the first accommodation opening S1.

As in the foregoing, in the detection element 10 in this example, the absorption layer 11 is supported from the side of the substrate 17 by the support 13 at a location close to the part exposed through the second accommodation opening S2 in the stacking direction Dz and the extension directions Dx and Dy. As a result, when the temperature of the detection element 10 rises, the part of the absorption layer 11 exposed through the second accommodation opening S2 is highly likely to warp in the direction away from the substrate 17, and contact and collision between the absorption layer 11 and the substrate 17 can be effectively avoided.

In this way, according to this example, damage to the absorption layer 11 and/or the substrate 17 attributable to warping of the absorption layer 11 when the temperature of the detection element 10 rises can be reduced, and the effects of warping that may occur in the detection element 10 can be effectively suppressed.

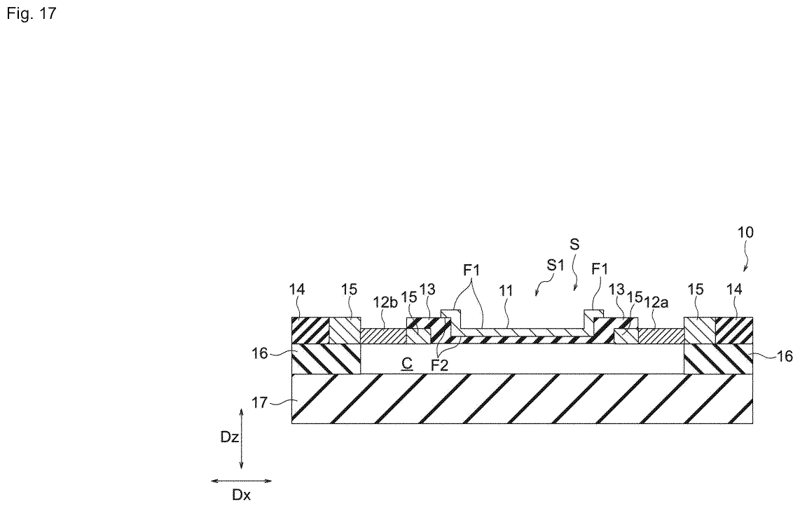

As will be described, the detection element 10 in this example is also advantageous in reducing the heat capacity and the time constant and has an excellent high-speed response as compared to the case where the entire second layer surface F2 of the absorption layer 11 is covered with the support 13 (see FIG. 17 (Comparative Example 2) which will be described below).

In particular, the cavity portion C is located on one side (the lower side in FIG. 5) of the part of the absorption layer 11 exposed through the second accommodation opening S2, and the space including the first accommodation opening S1 is located on the other side (the upper side in FIG. 5). Therefore, the detection element 10 in this example can keep the heat capacity small in the absorption layer 11 (particularly in the center part including the part exposed through the second accommodation opening S2) and adjacent regions thereof, which is advantageous in keeping the time constant, which is expressed as the product of the heat capacity and the thermal resistance, small.

The detection element 10 in this example can be easily manufactured without complex processing because of the simple shape of the second accommodation opening S2.

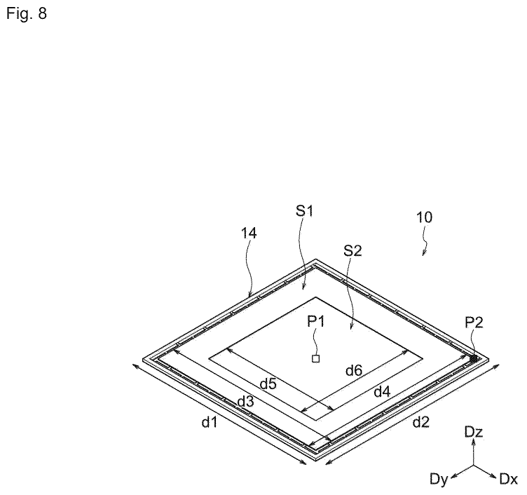

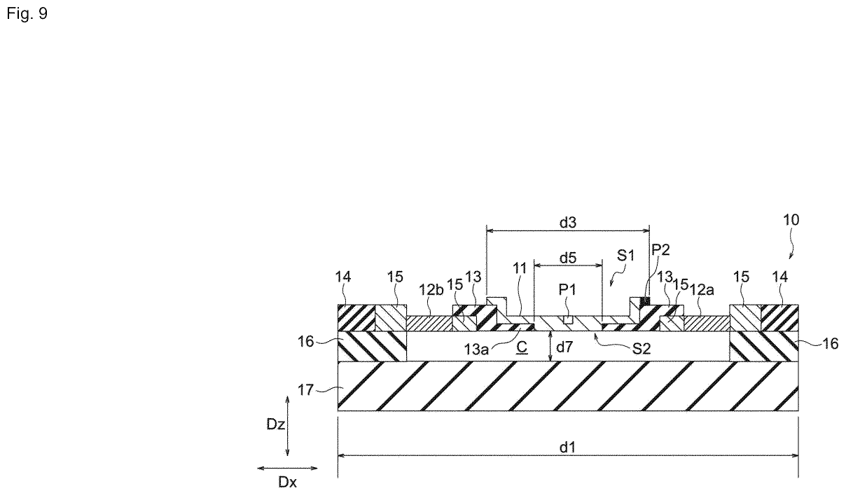

FIG. 8 is a view of the detection element 10 (particularly the detection element 10 according to Example 1) used as a simulation model, showing various sizes d1 to d6. FIG. 9 is a side cross-sectional view of an example of the detection element 10 according to Example 1, showing various sizes d1, d3, d5, and d7.

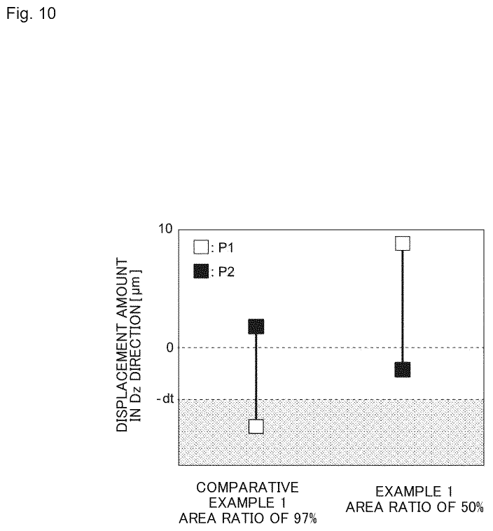

FIG. 10 is a graph showing simulation results about the displacement amount of the absorption layer 11 regarding Comparative Example 1 and Example 1. The ordinate in FIG. 10 represents the displacement amount (μm) of the absorption layer 11 (particularly first and second evaluation points P1 and P2) in the stacking direction Dz.

In FIG. 10, the part above 0 μm (i.e., the positive side) indicates that each evaluation point in the absorption layer 11 has been displaced to the side of the first accommodation opening S1 (the upper side in FIG. 9), away from the substrate 17. Meanwhile, the part below 0 μm in FIG. 10 (i.e., the negative side) indicates that each evaluation point in the absorption layer 11 has been displaced to the side of the substrate 17 (the lower side in FIG. 9). In particular, in FIG. 10, “−dt” is an evaluation reference value, and the range below “−dt” indicates the range where the absorption layer 11 and the substrate 17 may contact and collide with each other. Thus, “dt” is equal to “the spacing (distance) d7 in the stacking direction Dz between the part of the absorption layer 11 exposed through the second accommodation opening S2 and the substrate 17” at an expected environmental temperature (typically room temperature (e.g., about 20° C.)).

The inventor has actually conducted simulations to verify the advantageous effects brought about by the detection element 10 according to Example 1. Specifically, simulations for comparing the detection element 10 shown in FIGS. 2 and 3 (Comparative Example 1) with the detection element 10 shown in FIGS. 5 and 6 (Example 1) were conducted.

In the simulations for both Comparative Example 1 and Example 1, the pixel pitches d1 and d2 of the detection element 10 were set to 300 μm, and the maximum sizes d3 and d4 of the absorption layer 11 in the extension directions Dx and Dy were set to 271 μm. As for both Comparative Example 1 and Example 1, the “spacing d7 in the stacking direction Dz between the part of the absorption layer 11 exposed through the second accommodation opening S2 and the substrate 17,” which is equal to the size of the cavity portion C in the stacking direction Dz was set to 3.5 μm.

As for both Comparative Example 1 and Example 1, the size of the absorption layer 11 in the stacking direction Dz was set to 700 nm, and the size of the support 13 in the stacking direction Dz was set to 500 nm. As for both Comparative Example 1 and Example 1, the linear expansion coefficient of the absorption layer 11 was set to 9 ppm/K, and the linear expansion coefficient of the support 13 was set to 3.2 ppm/K.

As for Example 1, the sizes d5 and d6 of the part of the absorption layer 11 exposed through the second accommodation opening S2 in the extension directions Dx and Dy were set to 187 μm. Therefore, according to Example 1, the projected area of the part of the absorption layer 11 exposed through the second accommodation opening S2 in the stacking direction Dz (=d5×d6) was set to be about 50% (area ratio) of the projected area of the entire absorption layer 11 in the stacking direction Dz (=d3×d4).

Meanwhile, according to Comparative Example 1, regarding a direction perpendicular to the stacking direction Dz, the projected area of the part of the absorption layer 11 exposed through the second accommodation opening S2 in the stacking direction Dz was set to be about 97% (area ratio) of the projected area of the entire absorption layer 11 in the stacking direction Dz.

The displacement amounts of the first evaluation point P1 and the second evaluation point P2 of the absorption layer 11 in the stacking direction Dz were obtained by a simulation conducted when the detection element 10 satisfied the above conditions at room temperature (e.g., 20° C.), and the temperature of the entire detection element 10 reached 400° C.

The first evaluation point P1 is set at the center point of the absorption layer 11 as shown in FIGS. 8 and 9 and corresponds to the part of the absorption layer 11 exposed through the second accommodation opening S2. Meanwhile, the second evaluation point P2 is set at the outermost end of the absorption layer 11 and corresponds to the part of the absorption layer 11 that is not exposed through the second accommodation opening S2.

As a result of the simulation, as shown in FIG. 10, according to Comparative Example 1, the displacement amount of the second evaluation point P2 in the stacking direction Dz was a positive value, while the first evaluation point P1 was a negative value less than “−dt”. Therefore, as can be seen from Comparative Example 1, when the temperature of the detection element 10 rises, the part of the absorption layer 11 exposed through the second accommodation opening S2 warps toward the substrate 17 for a thickness equal to or greater than the depth of the cavity portion C and may come into contact with the substrate 17.

Meanwhile, according to Example 1, the displacement amounts of the first and second evaluation points P1 and P2 were greater than “−dt,” indicating that there is no possibility that the absorption layer 11 is in contact with the substrate 17. In particular, the displacement amount of the first evaluation point P1 (the center point) was located more on the positive side than the displacement amount of the second evaluation point P2 (the outermost end) and indicated a value (positive value) greater than 0 μm.

Therefore, as can be seen, according to Example 1, the part of the absorption layer 11 exposed through the second accommodation opening S2 does not warp toward the substrate 17 and does not contact and collide with the substrate 17 when the temperature of the detection element 10 rises.

### Example 2

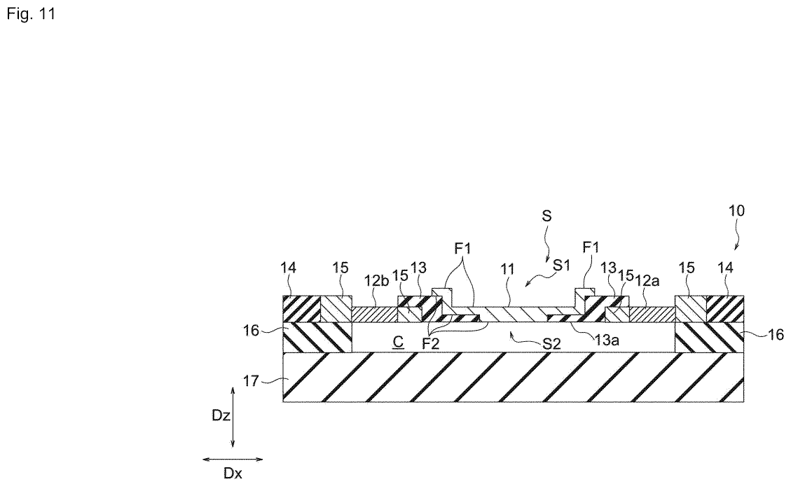

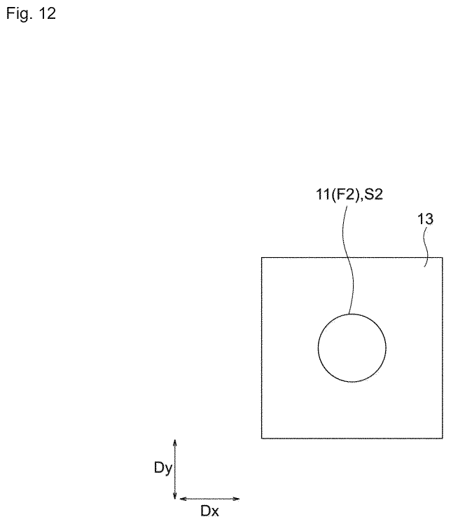

FIG. 11 is a side cross-sectional view of a detection element 10 according to Example 2 of the first embodiment. FIG. 12 is a plan view of the absorption layer 11 and the support 13 shown in FIG. 11 (particularly a view of the absorption layer 11 and the support 13 as viewed from below in FIG. 11).

In the present embodiment, elements that are the same as or correspond to those in the detection element 10 according to Example 1 described above will be denoted by the same reference signs, and detailed descriptions thereof will not be provided.

The second accommodation opening S2 in this example has a circular or oval planar shape. The “circular” here can also be described as an elliptical shape in which the two focal points coincide.

In the example shown in FIG. 12, the second accommodation opening S2 has a substantially perfect circle planar shape.

The other parts of the detection element 10 in this example have the same configuration as the detection element 10 according to Example 1.

The detection element 10 in this example is advantageous in relaxing the stress concentration that acts on the absorption layer 11 (particularly on the part exposed through the second accommodation opening S2) when the temperature rises.

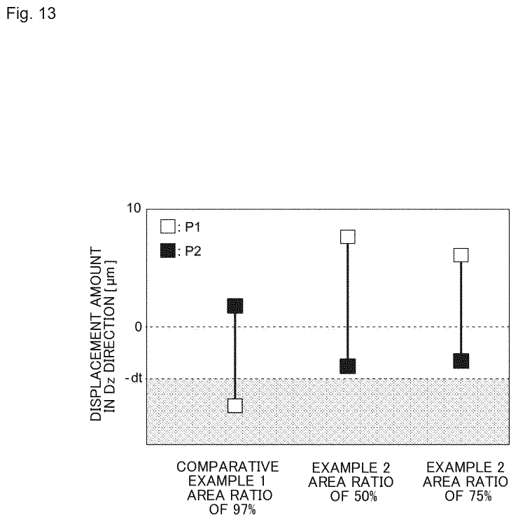

FIG. 13 is a graph showing simulation results about the displacement amount of the absorption layer 11 regarding Comparative Example 1 and Example 2. The ordinate in FIG. 13 represents the displacement amount (μm) of the absorption layer 11 (particularly the first evaluation point P1 and the second evaluation point P2) in the stacking direction Dz.

The inventor conducted simulations for Example 2 similarly to Example 1 to verify the advantageous effects brought about by the detection element 10 according to Example 2. Basically, the simulations for Example 2 were conducted under the same conditions as the simulation for Example 1 described above.

As for Example 2, however, the simulations were based on the detection element 10 (see FIG. 12), in which the second accommodation opening S2 had a substantially perfect circle planar shape.

As for Example 2, the size (diameter) of the part of the absorption layer 11 exposed through the second accommodation opening S2 was changed between the extension direction Dx and Dy, and the simulation was conducted for both the case where the area ratio of the part was 50% and the case where the area ratio of the part was 75%. The “area ratio” here refers to the ratio of the projected area of the part of the absorption layer 11 exposed through the second accommodation opening S2 in the stacking direction Dz to the projected area of the entire absorption layer 11 in the stacking direction Dz, similarly to Example 1 described above.

As can be understood from the results of the simulations, the absorption layer 11 (particularly the part exposed through the second accommodation opening S2) according to Example 2 also did not warp toward the substrate 17 and did not contact and collide with the substrate 17 when the temperature of the detection element 10 was raised.

### Example 3

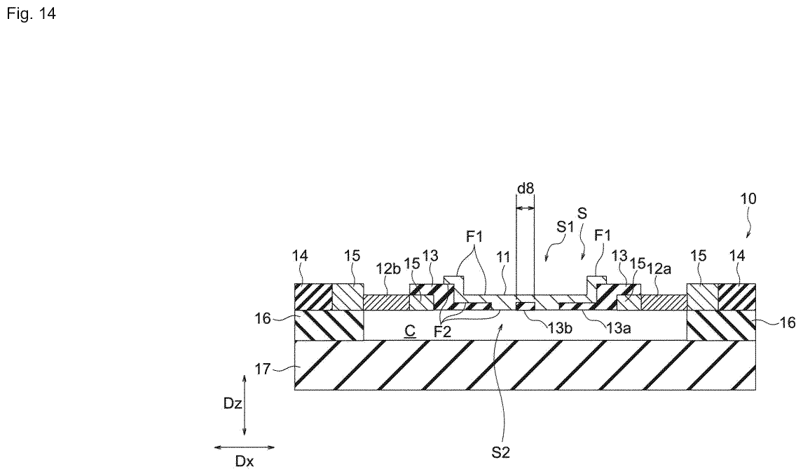

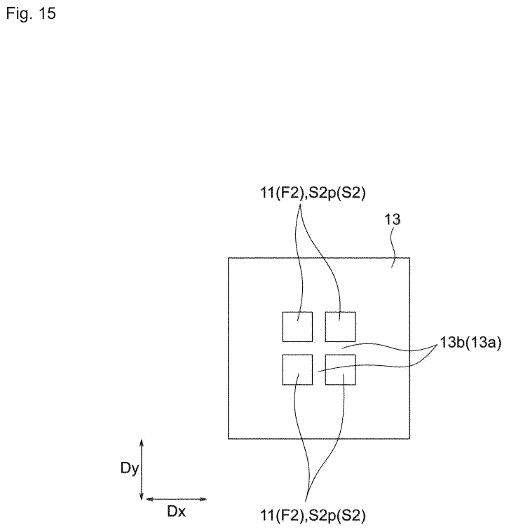

FIG. 14 is a side cross-sectional view of a detection element 10 according to Example 3 of the first embodiment. FIG. 15 is a plan view of the absorption layer 11 and the support 13 shown in FIG. 14 (particularly a view of the absorption layer 11 and the support 13 as viewed from below in FIG. 14).

In this example, elements that are the same as or correspond to those in the detection elements 10 according to Examples 1 and 2 described above will be denoted by the same reference signs, and detailed descriptions thereof will not be provided.

The second accommodation opening S2 in this example has a plurality of partial openings S2p separated from each other.

In the example shown in FIGS. 14 and 15, a part of the opening partition 13a that partitions the second accommodation opening S2 is formed as an opening separation portion 13b having a cross-shaped planar shape. The opening separation portion 13b of the opening partition 13a separates the second accommodation opening S2 into a plurality (four) of partial openings S2p. In other words, the partial openings S2p are separated from each other by the opening separation portion 13b.

The other parts of the detection element 10 in this example have the same configuration as the detection element 10 according to Examples 1 and 2.

The absorption layer 11 (particularly the part exposed through the second accommodation opening S2) in this example is directly supported by the opening separation portion 13b from the side of the substrate 17. Therefore, the detection element 10 in this example is advantageous in that the absorption layer 11 (particularly the part exposed through the second accommodation opening S2) is less likely to warp toward the substrate 17 when the temperature rises, and the deformation of the absorption layer 11 itself and the amount of deformation are reduced.

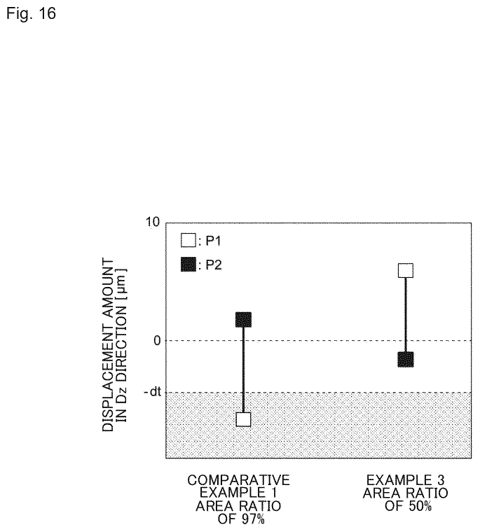

FIG. 16 is a graph showing simulation results about the displacement amount of the absorption layer 11 regarding Comparative Example 1 and Example 3. The ordinate in FIG. 16 represents the displacement amount (μm) of the absorption layer 11 (particularly the first evaluation point P1 and the second evaluation point P2) in the stacking direction Dz.

Similarly to Examples 1 and 2, the inventor conducted simulations for Example 3 to verify the advantageous effects brought about by the detection element 10 according to Example 3. Basically, the simulations for Example 3 were conducted under the same conditions as the simulations for Examples 1 and 2.

As for Example 3, however, the simulations were based on the detection element 10 (see FIGS. 14 and 15) in which four partial openings S2p were provided as the second accommodation openings S2.

As for Example 3, the width d8 of the opening separation portion 13b in the extension directions Dx and Dy was set to 70 μm, and the area ratio of the part of the absorption layer 11 exposed through the second accommodation opening S2 was set to 50%. Similarly to Examples 1 and 2, the “area ratio” here refers to the ratio of the projected area of the part of the absorption layer 11 exposed through the second accommodation opening S2 (in this example, four partial openings S2p) in the stacking direction Dz to the projected area of the entire absorption layer 11 in the stacking direction Dz.

As can be understood from the simulation results, the absorption layer 11 (particularly the part exposed through the second accommodation opening S2) according to Example 3 does not warp toward the substrate 17 either and does not contact and collide with the substrate 17 when the temperature of the detection element 10 rises.

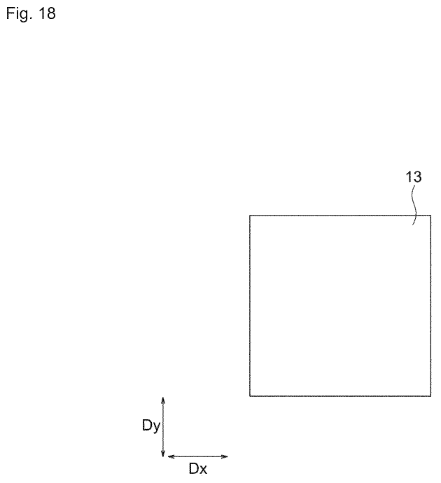

FIG. 17 is a side cross-sectional view of the detection element 10 according to Comparative Example 2. FIG. 18 is a plan view of the support 13 shown in FIG. 17 (particularly a view of the support 13 as viewed from below in FIG. 17).

In Comparative Example 2 shown in FIGS. 17 and 18, the accommodation space S is partitioned by the support 13 in a bottomed concave shape. In other words, the accommodation space S does not have a second accommodation opening S2 (see for example FIG. 2).

Therefore, the entire second layer surface F2 of the absorption layer 11 is in contact with the support 13, and the absorption layer 11 is not exposed at all toward the cavity portion C and the substrate 17. Therefore, the ratio (area ratio) of the projected area of the part of the absorption layer 11 exposed through the second accommodation opening S2 in the stacking direction Dz to the projected area of the entire absorption layer 11 in the stacking direction Dz is 0%.

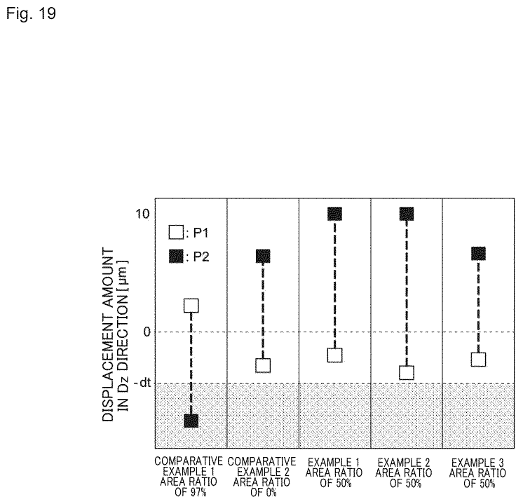

FIG. 19 is a graph showing simulation results about the displacement amount of the absorption layer 11 regarding Comparative Examples 1 and 2 and Examples 1 to 3. The ordinate in FIG. 19 represents the displacement amount (μm) of the absorption layer 11 (particularly the first evaluation point P1 and the second evaluation point P2) in the stacking direction Dz.

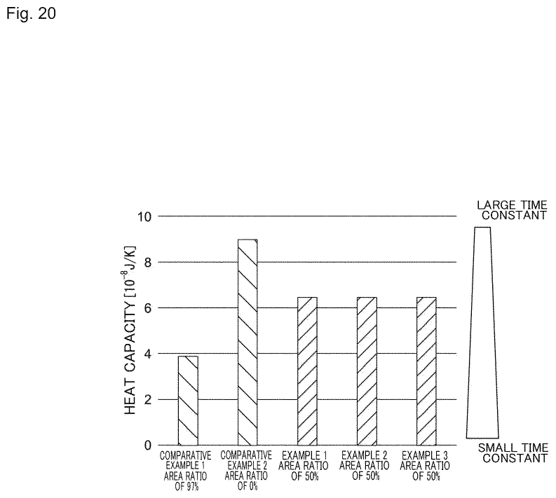

FIG. 20 is a graph showing the simulation results about the heat capacity of the detection element 10 regarding Comparative Examples 1 and 2 and Examples 1 to 3. The ordinate in FIG. 20 represents the heat capacity of the detection element 10 (10⁻⁸ J/K).

As for the warping of the absorption layer 11 (the displacement amount in the stacking direction Dz) during temperature increase as described above, good simulation results were obtained for Examples 1 to 3, while the simulation results for Comparative Example 1 indicate that the absorption layer 11 warped to be in contact with the substrate 17 (see FIG. 19).

As for Comparative Example 2, as shown in FIG. 19, similarly to Examples 1 to 3, the simulation results indicates that the absorption layer 11 warped toward the first accommodation opening S1 when the temperature of the detection element 10 was raised and did not contact and collide with the substrate 17.

However, the detection element 10 according to Comparative Example 2 had a larger heat capacity than the detection elements 10 according to Examples 1 to 3, as shown in FIG. 20, which is disadvantageous from the viewpoint of keeping the time constant (=heat capacity×thermal resistance) small. The detection element 10 according to Comparative Example 1 exhibited a smaller heat capacity than the detection elements 10 according to Examples 1 to 3.

As can be clearly understood from FIGS. 19 and 20, the detection element 10 according to Examples 1 to 3 is advantageous in achieving a good balance between “avoiding contact and collision between the absorption layer 11 and the substrate 17 during temperature increase” and “reducing the time constant.”

The detection elements 10 according to Comparative Examples 1 and 2 are merely shown as a counterpart to describe the advantageous effects brought about by the detection elements 10 according to Examples 1 to 3 and are not necessarily excluded from the inventive concept disclosed herein. In other words, it should be understood that the detection elements 10 according to Comparative Examples 1 and 2 can also be included in the concept of the invention disclosed herein.

### Second Embodiment

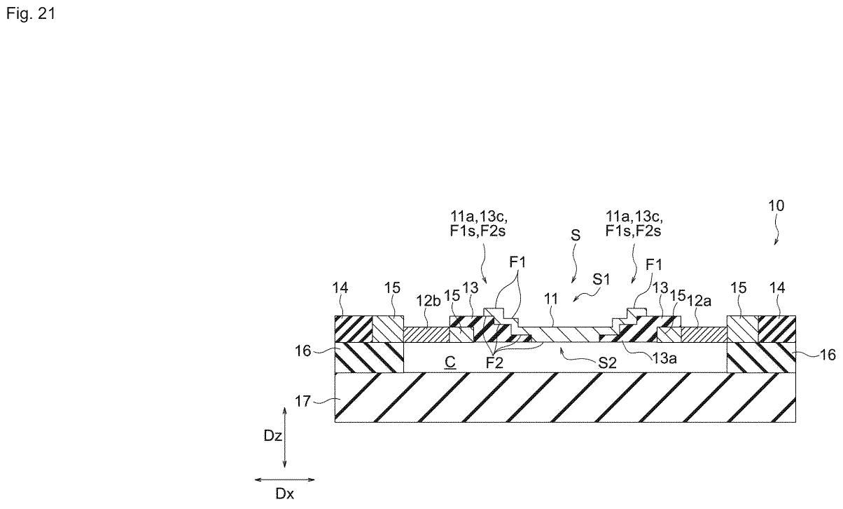

FIG. 21 is a side cross-sectional view of an example of a detection element 10 according to a second embodiment.

In the present embodiment, elements that are the same as or correspond to those of the detection element 10 according to the first embodiment described above (particularly the detection elements 10 according to the first to third embodiments) will be denoted by the same reference signs, and detailed description thereof will not be provided.

According to the embodiment, the support 13 has a plurality of steps (support steps 13c) and the absorption layer 11 has a plurality of steps (absorption steps 11a).

In the example shown in FIG. 21, the part of the support 13 that partitions the accommodation space S (i.e., the inner wall part of the support 13 located on the center side) includes a plurality of support steps 13c and forms a plurality of stepped surfaces. Meanwhile, the part of the absorption layer 11 that is directly supported by the support 13 (especially the support step 13c) (i.e., the outer peripheral part of the absorption layer 11) includes the absorption steps 11a.

The first layer surface F1 and the second layer surface F2 of the absorption layer 11 have a plurality of step-shaped portions F1s and F2s. In the example shown in FIG. 21, the outer peripheral parts of the first and second layer surfaces F1 and F2 are composed of step-shaped portions F1s and F2s, and the step-shaped portion F2s of the second layer surface F2 is in contact with the top surface of the support step 13c without a gap.

The second accommodation opening S2 shown in FIG. 21 has a quadrangular (square) planar shape, similarly to the second accommodation opening S2 according to the first embodiment, but the accommodation opening may have any planar shape. Thus, the second accommodation opening S2 according to the embodiment may have a circular or oval planar shape (see FIG. 12) or may have a plurality of partly opening portions (see FIG. 15) that are separated from each other.

The other parts of the detection element 10 have the same configuration as the detection element 10 according to the first embodiment.

The detection element 10 according to the embodiment including the absorption layer 11 with a stepped structure is advantageous in that improvement in the efficiency of receiving the detection wave L can be expected.

### Modifications

The detection element 10 described above can be applied to electronic devices other than the imaging system 100 (see FIG. 1). The imaging system 100 described above may also be used to image non-human entities (e.g., other animals, plants, and objects) and can be used for any application and purpose.

For example, the detection element 10 and the imaging system 100 may be applied to cameras for body checking at airports and other locations, surveillance cameras, devices for checking distributed items (including home delivery items), and other security devices. The detection element 10 and the imaging system 100 may be applied to a screening device for inspecting the inside of an object, a device for inspecting foreign objects mixed into an object, a device for measuring the thickness of an object, and a measuring device for checking the quantity of a content such as liquid and powder. The detection element 10 and the imaging system 100 may also be applied to medical devices for imaging affected areas and other devices used in the life science field.

Although the imaging system 100 shown in FIG. 1 is provided as a so-called active image sensor, the detection element 10 and the imaging system 100 may be applied to a passive image sensor that uses electromagnetic waves emitted from the subject itself as the detection wave L.

It should be noted that the embodiments and modifications disclosed herein are merely illustrative in all respects and should not be construed as limiting. The embodiments and modifications described above may be subject to various forms of omission, substitution, and change without departing from the scope and gist of the appended claims. For example, the embodiments and modifications described above may be combined in whole or in part, and an embodiment other than those described above may be combined with the embodiments or modifications described above. In addition, the advantageous effects of the present disclosure described herein are merely exemplary, and other effects may be provided as well.

Further, the technical category in which the above-described technical ideas are embodied is not limited. For example, the above-described technical ideas may be embodied by a computer program for causing a computer to execute one or more procedures (steps) included in the method for manufacturing or using the above-described devices. The above-described technical ideas may be embodied by a non-transitory computer-readable recording medium in which such a computer program is recorded.

### Supplementary Notes

The present disclosure can also be configured as follows.

### Item 1

A detection element comprising an absorption layer configured to receive an electromagnetic wave included in at least a part of a wavelength range from 100 μm to 3000 μm to generate heat;
a thermoelectric element configured to generate current corresponding to the heat generated by the absorption layer; and
a support having an accommodation space in which the absorption layer is positioned,
the accommodation space having a first accommodation opening located on a side on which the electromagnetic wave is incident and a second accommodation opening located on an opposite side to the first accommodation opening, the absorption layer exposed through the second accommodation opening having an area smaller than the first accommodation opening does.

### Item 2

The detection element according to item 1, wherein the absorption layer has a first layer surface and a second layer surface that is located on an opposite side to the first layer surface and partly exposed through the second accommodation opening, and
the support is partly in contact with the second layer surface.

### Item 3

The detection element according to item 2, wherein the second accommodation opening has an area which is at least 10% of a projected area of the first layer surface with respect to a stacking direction in which the absorption layer and the support are stacked on each other.

### Item 4

The detection element according to item 2 or 3, wherein the second accommodation opening has an area which is at most 75% of a projected area of the first layer surface with respect to a stacking direction in which the absorption layer and the support are stacked on each other.

### Item 5

The detection element according to any one of items 1 to 4, wherein the absorption layer has a linear expansion coefficient greater than the support does.

### Item 6

The detection element according to item 5, wherein the difference between the linear expansion coefficient of the absorption layer and the linear expansion coefficient of the support is at least 6 ppm/K.

### Item 7

The detection element according to any one of items 1 to 6, wherein the second accommodation opening has a polygonal planar shape.

### Item 8

The detection element according to any one of items 1 to 7, wherein the second accommodation opening has a circular or oval planar shape.

### Item 9

The detection element according to any one of items 1 to 8, wherein the second accommodation opening has a plurality of partial openings that are separated from each other.

### Item 10

The detection element according to any one of items 1 to 9, wherein the support has a stepped surface that partitions the accommodation space and is in contact with the absorption layer.

### Item 11

The detection element according to any one of items 1 to 10, wherein the absorption layer has a plurality of steps.

### Item 12

The detection element according to any one of item 2 and items 3 to 11 dependent from item 2, wherein the first layer surface has a plurality of step-shaped portions.

### Item 13

The detection element according to any one of items 1 to 12, wherein a part of the absorption layer exposed through the second accommodation opening curves toward the first accommodation opening as the temperature of the absorption layer rises.

### Item 14

The detection element according to any one of items 1 to 13, wherein the support has an opening partition that extends in a direction perpendicular to the stacking direction in which the absorption layer and the support are stacked on each other and partitions the second accommodation opening,
at least a part of the absorption layer is located on the opening partition, and the opening partition curves toward the first accommodation opening as the temperature rises.

### Item 15

The detection element according to any one of items 1 to 14, further comprising a structural member opposed to a part of the absorption layer exposed through the second accommodation opening.

### Item 16

The detection element according to any one of items 1 to 15, wherein the support has an insulating property.

### Item 17

An electronic device comprising a detection device,
the detection device comprising:
an absorption layer configured to receive an electromagnetic wave included in at least a part of a wavelength range from 100 μm to 3000 μm to generate heat;
a thermoelectric element configured to generate current corresponding to the heat generated by the absorption layer; and
a support having an accommodation space in which the absorption layer is positioned,
the accommodation space having a first accommodation opening located on a side on which the electromagnetic wave is incident and a second accommodation opening located on an opposite side to the first accommodation opening,
the absorption layer exposed through the second accommodation opening having an area smaller than the first accommodation opening does.

### Item 18

The electronic device according to item 17, wherein the absorption layer has a first layer surface and a second layer surface that is located on an opposite side to the first layer surface and partly exposed through the second accommodation opening, and
the support is partly in contact with the second layer surface.

### Item 19

The electronic device according to item 18, wherein the second accommodation opening has an area which is at least 10% of a projected area of the first layer surface with respect to a stacking direction in which the absorption layer and the support are stacked on each other.

### Item 20

The electronic device according to item 18 or 19, wherein the second accommodation opening has an area which is at most 75% of a projected area of the first layer surface with respect to a stacking direction in which the absorption layer and the support are stacked on each other.

### Item 21

The electronic device according to any one of items 17 to 20, wherein the absorption layer has a linear expansion coefficient greater than the support does.

### Item 22

The electronic device according to item 21, wherein the difference between the linear expansion coefficient of the absorption layer and the linear expansion coefficient of the support is at least 6 ppm/K.

### Item 23

The electronic device according to any one of items 17 to 22, wherein the second accommodation opening has a polygonal planar shape.

### Item 24

The electronic device according to any one of items 17 to 23, wherein the second accommodation opening has a circular or oval planar shape.

### Item 25

The electronic device according to any one of items 17 to 24, wherein the second accommodation opening has a plurality of partial openings that are separated from each other.

### Item 26

The electronic device according to any one of items 17 to 25, wherein the support has a stepped surface that partitions the accommodation space and is in contact with the absorption layer.

### Item 27

The electronic device according to any one of items 17 to 26, wherein the absorption layer has a plurality of steps.

### Item 28

The electronic device according to any one of item 18 and items 19 to 27 dependent from item 18, wherein the first layer surface has a plurality of step-shaped portions.

### Item 29

The electronic device according to any one of items 17 to 28, wherein a part of the absorption layer exposed through the second accommodation opening curves toward the first accommodation opening as the temperature of the absorption layer rises.

### Item 30

The electronic device according to any one of items 17 to 29, wherein the support has an opening partition that extends in a direction perpendicular to the stacking direction in which the absorption layer and the support are stacked on each other and partitions the second accommodation opening,
at least a part of the absorption layer is located on the opening partition, and the opening partition curves toward the first accommodation opening as the temperature rises.

### Item 31

The electronic device according to any one of items 17 to 30, further comprising a structural member opposed to a part of the absorption layer exposed through the second accommodation opening.

### Item 32

The electronic device according to any one of items 17 to 31, wherein the support has an insulating property.

### REFERENCE SIGNS LIST

10 Detection element
11 Absorption layer
11a Absorption step
12a First thermoelectric element
12b Second thermoelectric element
13 Support
13a Opening partition
13b Opening separation portion
13c Support step
14 First insulating layer
15 Lead
16 Second insulating layer
17 Substrate
100 Imaging system
101 Wave transmission unit
102 Wave receiving unit
103 Control unit
104 Terminal device
110 Optical system
111 Imaging unit
200 Subject
201 Clothing
210 Portable article
A Thermoelectric current
C Cavity portion
Dx Extension direction
Dy Extension direction
Dz Stacking direction
F1 First layer surface
F1s Step-shaped portion
F2 Second layer surface
F2s Step-shaped portion
L Detection wave
P1 First evaluation point
P2 Second evaluation point
S Accommodation space
S1 First accommodation opening
S2 Second accommodation opening
S2p Partial opening

1. A detection element comprising an absorption layer configured to receive an electromagnetic wave included in at least a part of a wavelength range from 100 μm to 3000 μm to generate heat;
a thermoelectric element configured to generate current corresponding to the heat generated by the absorption layer; and
a support having an accommodation space in which the absorption layer is positioned,
the accommodation space having a first accommodation opening located on a side on which the electromagnetic wave is incident and a second accommodation opening located on an opposite side to the first accommodation opening,
the absorption layer exposed through the second accommodation opening having an area smaller than the first accommodation opening does.

2. The detection element according to claim 1, wherein the absorption layer has a first layer surface and a second layer surface that is located on an opposite side to the first layer surface and partly exposed through the second accommodation opening, and
the support is partly in contact with the second layer surface.

3. The detection element according to claim 2, wherein the second accommodation opening has an area which is at least 10% of a projected area of the first layer surface with respect to a stacking direction in which the absorption layer and the support are stacked on each other.

4. The detection element according to claim 2, wherein the second accommodation opening has an area which is at most 75% of a projected area of the first layer surface with respect to a stacking direction in which the absorption layer and the support are stacked on each other.

5. The detection element according to claim 1, wherein the absorption layer has a linear expansion coefficient greater than the support does.

6. The detection element according to claim 5, wherein the difference between the linear expansion coefficient of the absorption layer and the linear expansion coefficient of the support is at least 6 ppm/K.

7. The detection element according to claim 1, wherein the second accommodation opening has a polygonal planar shape.

8. The detection element according to claim 1, wherein the second accommodation opening has a circular or oval planar shape.

9. The detection element according to claim 1, wherein the second accommodation opening has a plurality of partial openings that are separated from each other.

10. The detection element according to claim 1, wherein the support has a stepped surface that partitions the accommodation space and is in contact with the absorption layer.

11. The detection element according to claim 1, wherein the absorption layer has a plurality of steps.

12. The detection element according to claim 2, wherein the first layer surface has a plurality of step-shaped portions.

13. The detection element according to claim 1, wherein a part of the absorption layer exposed through the second accommodation opening curves toward the first accommodation opening as the temperature of the absorption layer rises.

14. The detection element according to claim 1, wherein the support has an opening partition that extends in a direction perpendicular to the stacking direction in which the absorption layer and the support are stacked on each other and partitions the second accommodation opening,
at least a part of the absorption layer is located on the opening partition, and the opening partition curves toward the first accommodation opening as the temperature rises.

15. The detection element according to claim 1, further comprising a structural member opposed to a part of the absorption layer exposed through the second accommodation opening.

16. The detection element according to claim 1, wherein the support has an insulating property.

17. An electronic device comprising a detection device,
the detection device comprising:
an absorption layer configured to receive an electromagnetic wave included in at least a part of a wavelength range from 100 μm to 3000 μm to generate heat;
a thermoelectric element configured to generate current corresponding to the heat generated by the absorption layer; and
a support having an accommodation space in which the absorption layer is positioned,
the accommodation space having a first accommodation opening located on a side on which the electromagnetic wave is incident and a second accommodation opening located on an opposite side to the first accommodation opening,
the absorption layer exposed through the second accommodation opening having an area smaller than the first accommodation opening does.
